(19) United States
(12) Patent Application Publication
(10) Pub. No.: US 2016/0247956 A1
(43) Pub. Date: Aug. 25, 2016

(54) Transistor Barrier-Controlled Internal Photoemission Detector

(71) Applicant: Dee-Son Pan, Los Angeles, CA (US)

(72) Inventor: Dee-Son Pan, Los Angeles, CA (US)

(21) Appl. No.: 15/049,079

(22) Filed: Feb. 21, 2016

Related U.S. Application Data
(60) Provisional application No. 62/176,458, filed on Feb. 20, 2015.

(51) Int. Cl. H01L 31/11; H01L 31/0304; H01L 31/028; H01L 31/113; H01L 31/0232

(52) U.S. Cl. CPC H01L 31/1105; H01L 31/1136; H01L 31/02327; H01L 31/028; H01L 31/0304

(57) ABSTRACT

A three-terminal transistor-based radiation detector is presented which uses internal photoemission over a bias-controlled potential barrier which may be of a bipolar or field-effect transistor nature. The proposed invention allows bias-tunable control of the radiation wavelength under detection while enabling integration with conventional silicon or other semiconductor fabrication processes. Furthermore, internal amplification of the photocurrent is possible via the use of impact ionization in the device, as well as current gain in a bipolar transistor structure.

### CROSS-REFERENCE TO RELATED APPLICATIONS

This application claims priority to U.S. provisional application entitled “Impact Ionized Absorbed Carrier Transistor (IMPACT) for Infrared Detection,” having Ser. No. 62/176,458 filed on Feb. 20, 2015, which is entirely incorporated herein by reference.

### STATEMENT REGARDING FEDERALLY SPONSORED RESEARCH OR DEVELOPMENT

Not applicable.

### REFERENCE TO SEQUENCE LISTING, A TABLE, OR A COMPUTER PROGRAM LISTING COMPACT DISC APPENDIX

Not applicable.

### BACKGROUND OF THE INVENTION

The present invention is in the field of electromagnetic radiation detection. Specifically, the invention pertains to a new semiconductor device capable of sensing electromagnetic radiation, particularly infrared radiation. Because of the usefulness of the infrared spectrum for numerous applications including surveillance, night vision, and spectroscopy, a host of materials, device structures, and physical mechanisms for infrared detection have been explored, all seeking a combination of optimal performance and cost effectiveness. These devices may be broadly divided into thermal and photonic detectors. Thermal detectors, which include thermopiles, pyroelectrics, and microbolometers, rely on the sensitivity of specific materials to temperature changes induced by incident infrared radiation. These devices generally allow for room temperature operation and are comparatively cheaper to manufacture, but have reduced detectivity and face important challenges to further cost reduction and technology improvement. For instance, the need for thermal isolation for microbolometers necessitates expensive vacuum packaging and inhibits pixel size scaling, limiting the resolution of bolometer-based sensor focal plane arrays (FPAs) for imaging purposes.

Photonic detectors utilize the excitation of electrons or holes in semiconductor structures by infrared photons to generate a current or voltage signal. As an example, mercury cadmium telluride (MCT) is frequently used because its optical band gap can be tuned within the range of energies corresponding to infrared photons, allowing electrons and holes to be created by impinging infrared photons exciting a valence band electron into a conduction band state. These electrons and holes are separated by electric fields and collected at electrodes to provide an electrical response. Another popular concept uses alternating layers of different III-V or II-VI semiconductors to create quantum well (QWIP) or superlattice photodetectors, where electrons are excited between different states of the quantized energy bands. Photonic detectors can achieve high sensitivity (or detectivity, the standard metric for these devices), but are generally costly to fabricate and maintain due to the materials used as well as the need for low temperature operation to reduce noise. Finally, internal photoemission (IPE) photodetectors utilize the injection of charge carriers excited by free carrier absorption over potential barrier; this includes metal-semiconductor Schottky barrier (SB) detectors, where electrons in the metal absorb energy from incident light and can induce current by photoemission into the semiconductor, provided the incident photons are of higher energy than the Schottky barrier height. All-semiconductor based variations such as homojunction interfacial work function detectors, heterojunction interfacial work function detectors, and split-off band infrared detectors operate in similar ways, where free carrier absorption is induced inside doped semiconductor regions and the excited carriers pass over a barrier created by an inhomogeneous doping profile, semiconductor heterojunction, or combination thereof. Such devices, however, tend to suffer from low quantum efficiencies because of short carrier mean free paths, which leads to momentum randomization via scattering that prevents photoexcited carrier collection, as well the lack of tenability over the barrier height.

All these devices face a further difficulty in that the readout integrated circuitry (ROIC) needed to process and output the detector infrared signals generally requires silicon-based transistors and circuits, whether in discrete or integrated complementary metal-oxide-semiconductor (CMOS) form. This leads to increased packaging and hybridization costs in connecting the infrared active elements or arrays with the silicon circuitry, as well as hampering integration of more sophisticated image processing and other functionalities. Because of advances in the metal-oxide-semiconductor field effect transistor (MOSFET) and CMOS, the cost and achievable minimum feature size of silicon CMOS-compatible technologies has been continuously improving for decades, in contrast to many of the infrared detection devices listed above. Therefore, a silicon-based infrared detector which can be manufactured in a CMOS-compatible process would have tremendous value by allowing cost reduction and size scaling while improving ROIC integration. Unfortunately, silicon is generally understood to be an unfavorable material for infrared detection because of its large optical band gap, which precludes absorption of infrared radiation beyond approximately 1.1 μm.

The invention described here overcomes this limitation by using free carrier absorption (FCA) in heavily doped semiconductors, including silicon; these optical transitions are continuum intraband processes and hence occur at any wavelength, in contrast to interband absorption or bound-to-bound and bound-to-continuum transitions in MCT, QWIPs, QDIPs, and many other IR detectors. SB or IPE photodetectors also use FCA in metals or doped semiconductors, but lack the additional gain mechanisms of this invention enumerated below. Finally, the cutoff wavelength of the invention can be adjusted by external electrical bias, allowing the same device to be used to detect radiation of different wavelengths.

### BRIEF SUMMARY OF THE INVENTION

The objective of the invention is to provide a three-terminal photodetector that can be implemented in a transistor architecture, such as a bipolar junction transistor (BJT) or field-effect transistor (FET), and can provide electrically tunable detection of radiation of different wavelengths. The present invention utilizes internal photoemission inside a transistor structure to absorb radiation and inject photo-excited carriers over a bias-controlled potential barrier inside the transistor to generate an output electrical current signal. Internal amplification of the photocurrent signal can be generated by utilizing the transistor action, for example using bipolar current gain if a BJT structure is utilized, as well as impact ionization in the transistor region. The detector may be used as a standalone element in many applications, including, but not limited to, gas and chemical infrared detection and spectroscopy, or as part of a FPA for infrared imaging. The device may fabricated using silicon or other semiconductor materials using conventional semiconductor processing techniques.

### BRIEF DESCRIPTION OF DRAWINGS

FIG. 1 is a band diagram explaining the operating principle of the invention;

FIG. 2 is a top view of one possible realization of the invention in a bipolar transistor structure;

FIG. 3 is the corresponding side-view of one possible realization of the invention in a bipolar transistor structure along with a possible doping profile;

FIG. 4 is a side view of another possible realization of the invention in a metal-oxide-semiconductor field-effect transistor structure;

FIG. 5 is the corresponding top-view of another possible realization of the invention in a metal-oxide-semiconductor field-effect transistor structure;

FIG. 6 is the corresponding side view of another possible realization of the invention in a metal-oxide-semiconductor field-effect transistor structure illustrating possible radiation illumination strategies;

FIG. 7 is a graph of the absorption coefficient in n-typed doped silicon as a function of photon energy and doping concentration;

FIG. 8 is a graph of the mean free path in n-typed doped silicon as a function of electron energy and doping concentration.

### DETAILED DESCRIPTION OF THE INVENTION

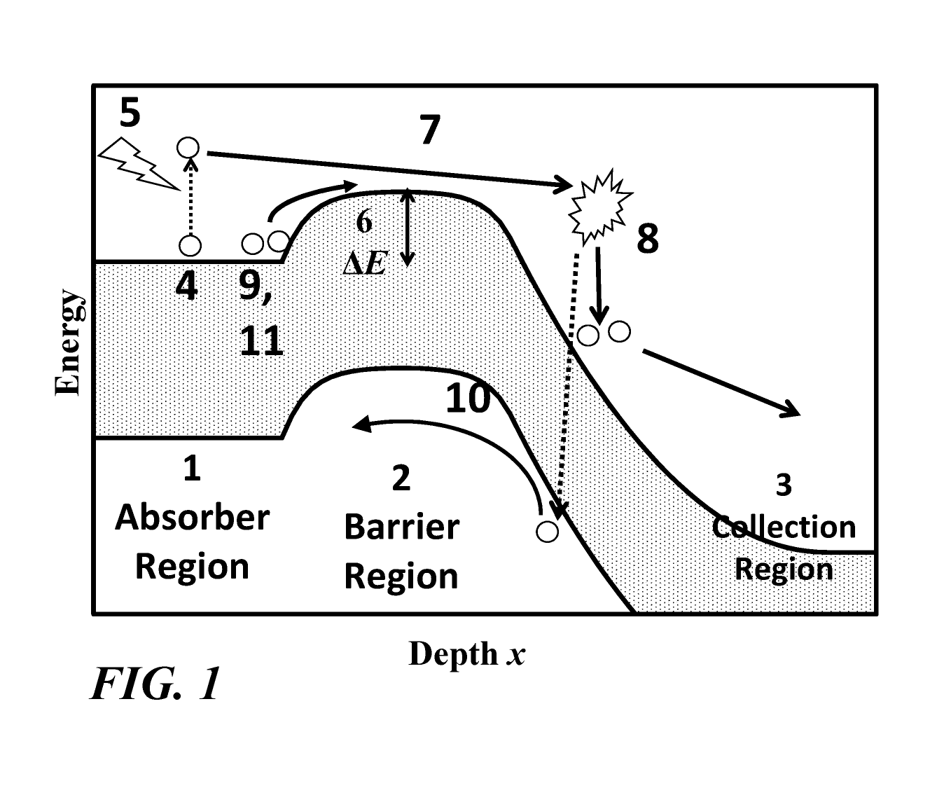

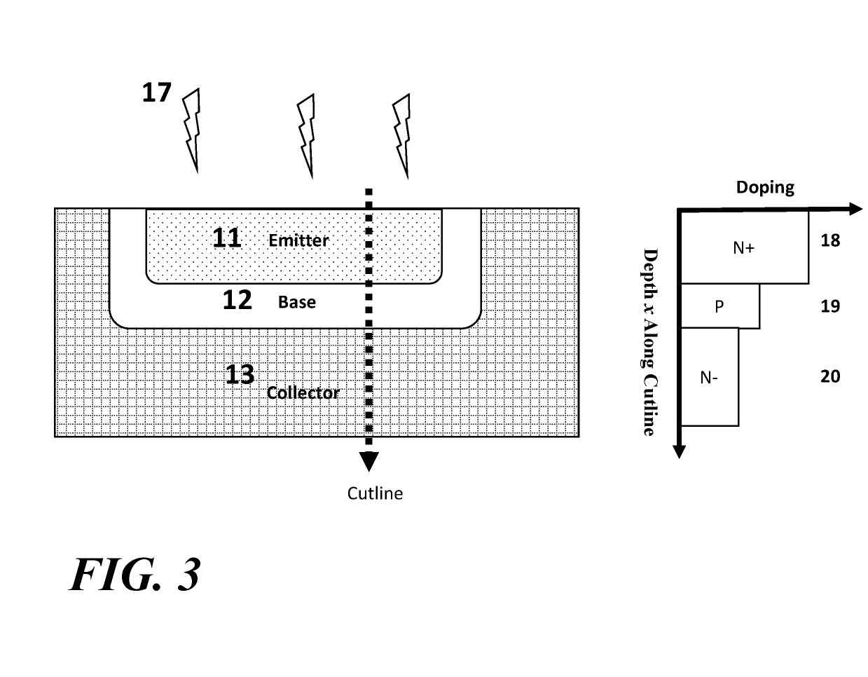

The present invention is an electromagnetic radiation detector element. The crucial advantages of the present invention include its high internal gain, tunable wavelength response, controllable dark current (not limited by tunneling), and low cost fabrication. The device achieves these features by utilizing transistor behavior, which can be implemented using either a bipolar junction transistor (BJT) or field-effect transistor (FET) structure. The operating mechanism for either embodiment of the present invention is schematically depicted in FIG. 1 by a device band diagram, where the three central regions of the device are denoted as the absorber region 1, barrier region 2, and collection region 3, respectively, where junction potentials between 1 and 2 and 2 and 3 may be established via a combination of chemical doping, material choice, and electrical biasing. The operating process in this figure is depicted for conduction band free electrons in semiconductors, but it is understood that the same mechanism can be utilized via suitable material and doping choice for valence band holes. The signal generation process is pictured in FIG. 3 and begins with energetic excitation of free carriers 4 in the absorber region by free carrier absorption (FCA) of incident photons 5. If the incident light is of a wavelength whose energy exceeds that of the absorber region-barrier region barrier height ΔE 6, a fraction of the photo-excited carriers can diffuse from the absorber region across the barrier region to the collection region 7, constituting a photocurrent. If the electrostatic potential in the junction between the barrier and collector regions exceeds the material band gap and the electric field in the junction exceeds the impact ionization threshold, impact ionization can occur for the photo-excited carriers drifting through the junction depletion region 8, amplifying the photocurrent via avalanche gain.

How these regions are constructed in practice may vary depending on the type of transistor architecture chosen. In one possible embodiment of the device, where an npn BJT is used as the underlying transistor structure, the absorber region 1 would be a heavily doped n-type emitter, the barrier region 2 would be the p-type doped base, and the collection region 3 would be an n-type doped collector. In another possible embodiment of the device, an n-type FET such as a metal-oxide-semiconductor field-effect transistor (MOSFET) would be used as the underlying transistor, in which case the absorber region 1 would correspond to the heavily n-type doped source, the barrier region 2 would be the p-type doped channel, and the collection region 3 would be the heavily n-type doped drain. In practice the device doping profiles may be more spatially inhomogeneous to improve electron transport and absorption, while preserving the basic operating principle. Those skilled in the art will recognize that embodiments utilizing holes as the primary photo-excited carrier type may be constructed by changing the doping and bias polarities of the device. While the implementation shown in FIG. 1 depicts a structure using semiconductor homojunctions where the entire device region is constructed using a single semiconductor material, those skilled in the art will recognize that embodiments using semiconductor heterojunctions may be used as well, taking advantage of heterojunction transistor structures, including, but not limited to, single and double heterojunction bipolar transistors (HBTs) or high-electron mobility transistors (HEMTs).

Whether a FET or BJT-based transistor structure is used, it is possible to select the cutoff wavelength of detectable radiation by changing the barrier height energy ΔE 6 in FIG. 1 using electrical bias. In a BJT architecture, this may be accomplished by directly modulating the voltage applied across the barrier (base) and absorber (emitter) junction. In a FET structure, changing the gate voltage with respect to the source voltage will similarly change the maximum barrier height at the interface between the channel and the source. In this way, voltage tuning of the wavelength of radiation detection can be accomplished.

If a BJT-type structure is used for the present invention, an additional photocurrent amplification process may be possible by utilizing the internal gain β of BJTs. This occurs because the photocurrent 7 can trigger an additional current flow of thermalized emitter electrons by modulating the emitter-base barrier height ΔE, yielding a bipolar injection gain 9 similar to the transistor gain β in ordinary BJTs. Furthermore, if impact ionization of the photocurrent is allowed 8, the avalanche-generated holes also pass into the base 10 and trigger addition bipolar gain 11 until steady state is reached. Therefore two gain mechanisms are present to yield greater total photocurrent amplification.

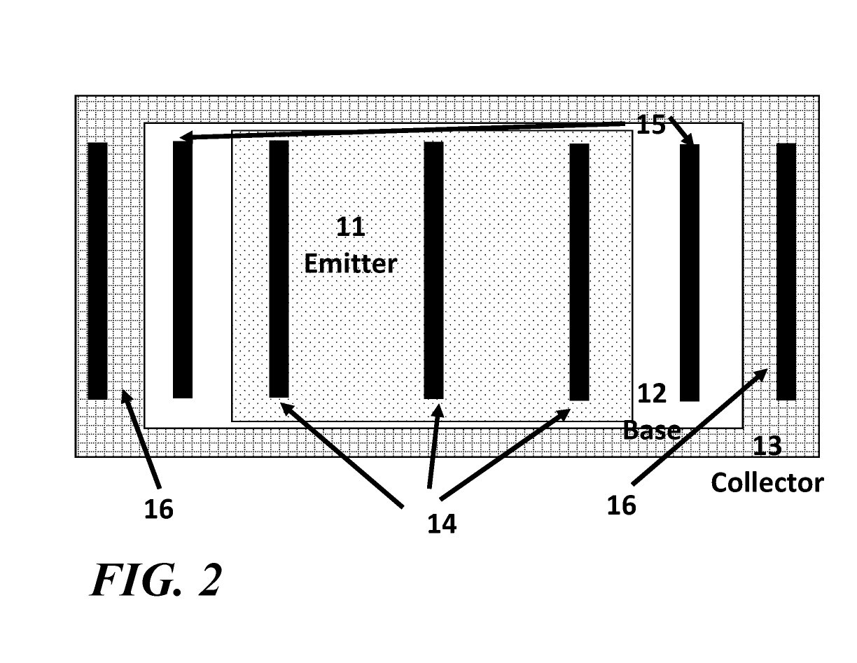

One possible BJT-based embodiment of the present invention is shown in FIGS. 2 and 3, based on that of silicon BJTs and phototransistors; this allows it to be fabricated using well-established commercial silicon processes. In the top view of one possible instance of the device depicted in FIG. 2, it comprises an n-type emitter 11, p-type base 12, and n-type collector 13, with corresponding metal contacts 14, 15, and 16 to the emitter, base, and collector, respectively. These regions correspond to the absorber, barrier, and collection regions of the device, respectively. The doping profile along a vertical cut of the device is illustrated in FIG. 3, where incident radiation 17 can access the transistor structure with a heavily doped emitter 18, lower and oppositely doped base 19, and low doped collector 20. In practice the device doping profiles may be substantially more inhomogeneous and modified to improve electron transport and absorption while preserving the basic operating principle. In some embodiments, epitaxial layers of semiconductor may be grown to form the various transistor regions.

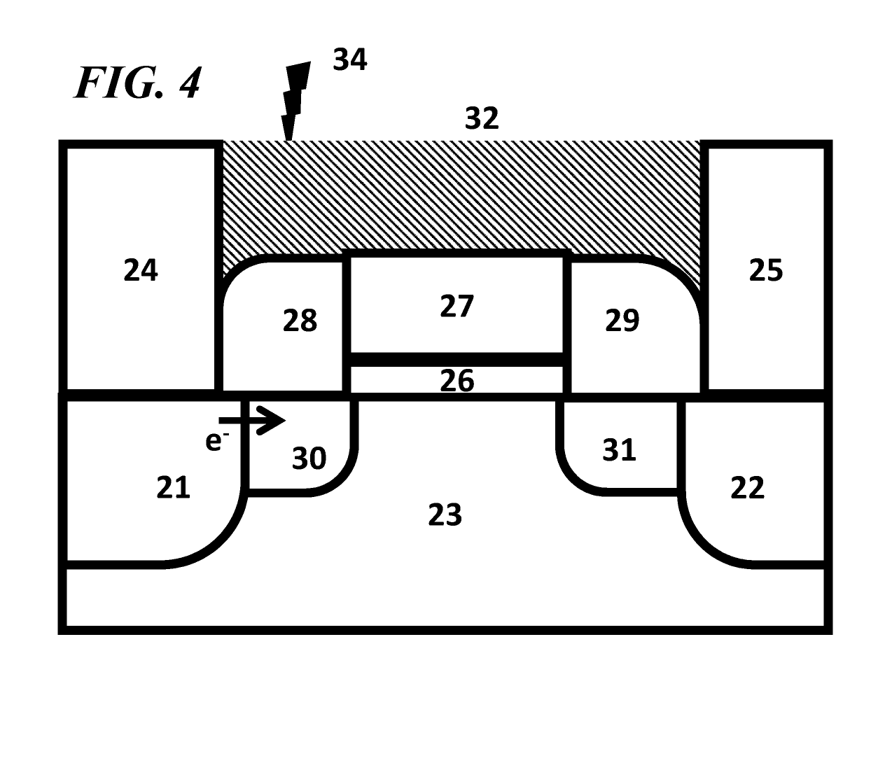

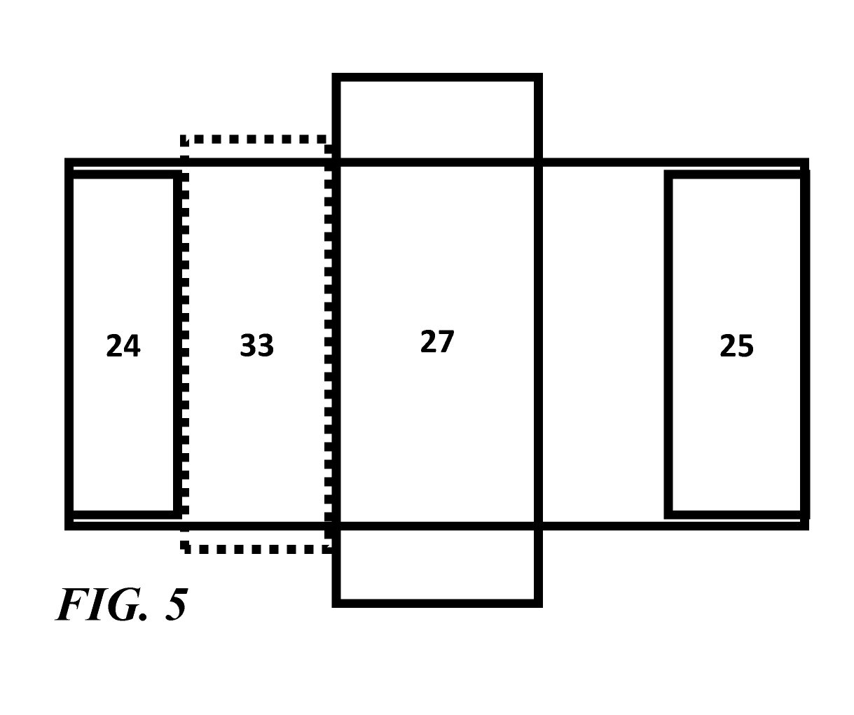

Another possible MOSFET-based embodiment of the present invention is shown in FIGS. 4 and 5, which provide side and top views of the structure, respectively. In this embodiment, a planar MOSFET has a heavily doped source or absorber region 21 and drain or collection region 22 with N-type dopants on a P-type substrate 23. This corresponds to an n-type MOSFET; alternatively, by reversing the polarity of doping, a p-type MOSFET can be realized. Contact plugs 24 and 25 made of a metal provide electrical contacts to the source and drain respectively. It is possible, though optional, that the region directly underneath the metal contacts within the source and drain may be formed of some metal silicide. The transistor gate oxide 26 and gate 27 cover the substrate channel, with spacers 28 and 29 formed of some dielectric material surrounding each side. Source and drain extensions (SDE) 30 and 31 which are also heavily doped but shallower than the junctions 21 and 22 may penetrate in the substrate underneath the spacers. The region 32 above the transistor substrate not taken up with the gate or contacts may be filled in with some dielectric. A top view corresponding to the schematic structure discussed here is shown in FIG. 2. In this embodiment, the region of the substrate 23 underneath the gate 27 will comprise the channel or barrier region. The substrate may be electrically tied to the source potential or it may be electrically biased separately from the source and drain to provide an additional degree of control over the channel potential.

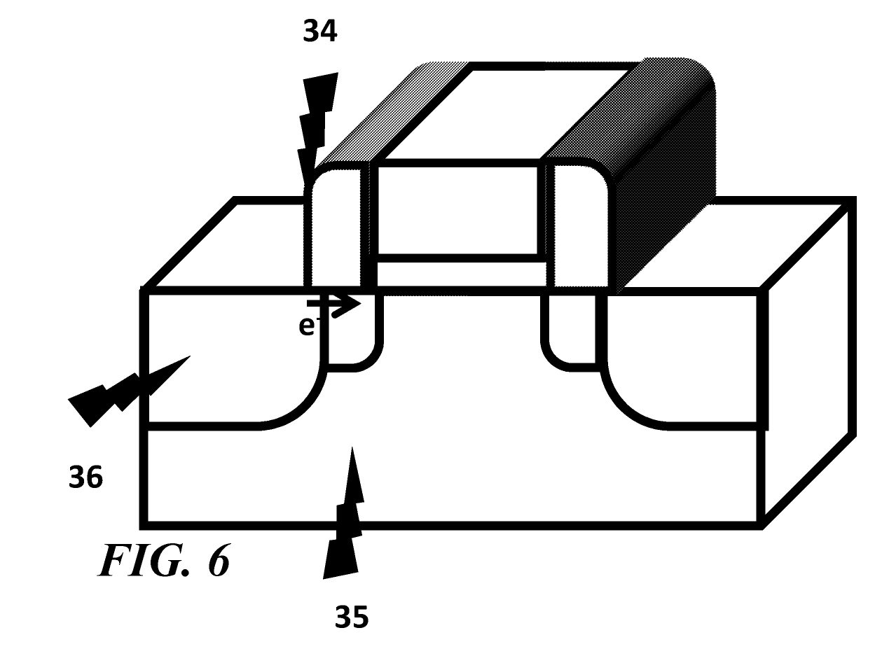

In the embodiment shown in FIGS. 4 and 5, the device operates by energetic excitation of free carriers through light absorption in the source 21 and source-side SDE 30 regions, which comprise the absorber region in this embodiment. As shown in FIG. 6, photons can reach the absorber region in several ways, through top illumination 34, back illumination 35, or lateral incidence 36. For the case of top illumination, as shown in FIGS. 4 and 5, the region 33 above the source 1 and between the gate 27 and the source contact plug 24 is marked and will be referred to as the “infrared window.” The infrared window extends up through all layers of interconnects and metallization that will be deposited on top of the substrate and is to be filled with an infrared-transparent dielectric or dielectrics. Infrared radiation incident normal to the substrate, represented as 34 in FIG. 4, can then penetrate through the infrared window to reach the underlying portion of the absorber region underneath. In the case of back illumination 35, incident photons pass through the substrate to the absorber region. Either of these configurations is suitable for imaging and other purposes where externally generated photons are detected. Lateral illumination 36 is useful for detecting photons in waveguides or other on-wafer structures which can be end-coupled or evanescently coupled to the detector. Similar illumination schemes are also possible for BJT-based embodiments of the present invention.

In the BJT embodiments of the present invention, FCA in the emitter is used as the radiation absorption mechanism, in contrast to conventional phototransistors which rely on interband absorption in the base. In conventional phototransistors, the cutoff wavelength of detectable radiation is not tunable but fixed by the magnitude of the band gap in the base. Therefore, in the present invention the range of detectable wavelengths is not limited by the band gap of the device material but only by the barrier height ΔE, which can be extended across a wide spectrum of radiation by suitable choice of junction built-in potential and biasing. Similarly, the FET embodiments of the present invention differ from conventional MOSFET-based phototransistors which utilize impurity absorption optical transitions in the channel rather than absorption in the source, again allowing for bias control of the cutoff wavelength. The transistor structure of all embodiments of the present invention introduces a critical element not present in conventional two-terminal IPE-based photodetectors like SB infrared detectors or homojunction or heterojunction interfacial workfunction IPE detectors, where the barrier height is set by material and doping properties, preventing tunable wavelength detection.

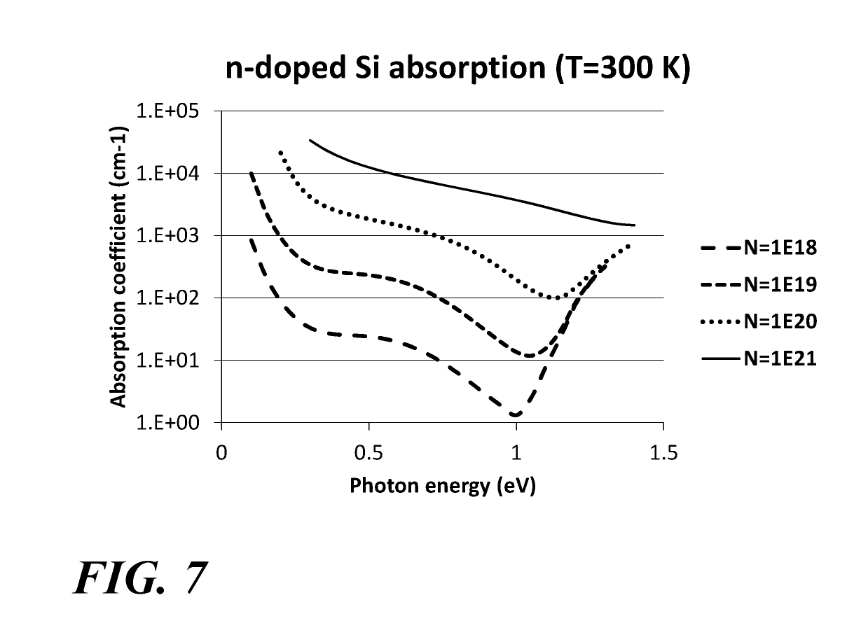

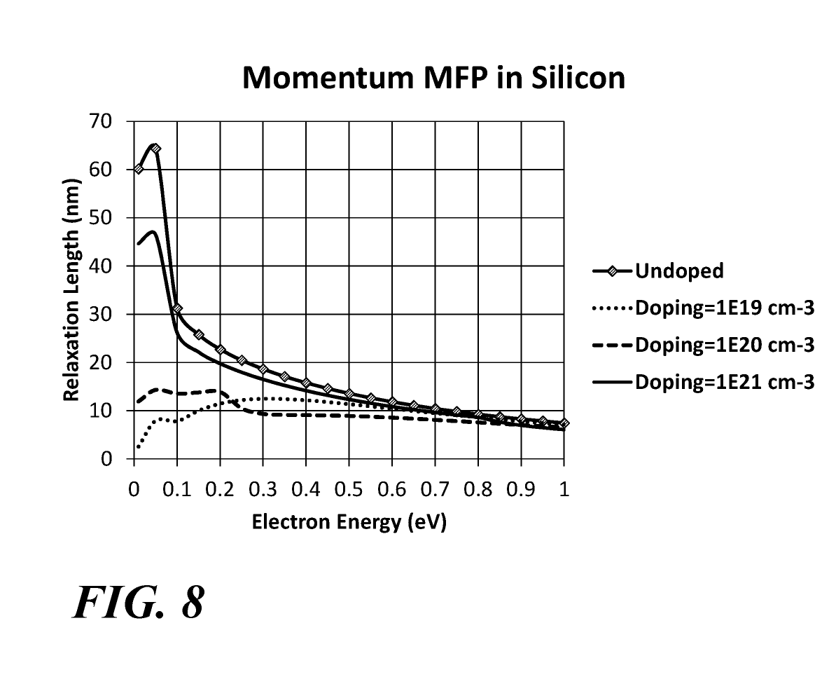

A further advantage of the present invention, particularly in FET-based embodiments, is the greater degree of control it offers over the length of the barrier region, which impacts the quantum efficiency of the device. Because intraband FCA requires a high density of mobile carriers and does not generate new electrons in the conduction or valence band, the production of an electrical signal from optical absorption occurs differently from ordinary photodiodes. Referring to FIG. 1, absorbed photons 5 energetically excite “hot” electrons 7 (assuming n-doped absorber region) in the neutral region of the heavily doped absorber region with random momenta. These hot electrons will then lose their excess momentum and energy through scattering off impurities, phonons, and other electrons. In a bulk homogeneous semiconductor, these dissipative processes are isotropic and no net charge flow occurs (though the material may heat up due to phonon emission by hot electrons). However, in the present invention, asymmetry is introduced by the oppositely doped barrier region and the resulting potential barrier ΔE. Excited electrons in the absorber region that drift away from the junction will eventually lose their energy and produce no signal. Nonetheless, some hot electrons will diffuse across the barrier region to the collection region 7, provided they have initial momenta directed towards the junction and sufficient energy to pass over the barrier energy ΔE. The efficiency of the FCA process and the resulting current response depends on the magnitude of the absorption as well as the mean free path (MFP) of excited electrons in the absorber region. These are controlled by the electron scattering mechanisms in the source material, including lattice vibrations (phonons) and the concentration of impurities (dopants). In FIG. 7 the calculated absorption coefficient due to FCA in silicon is shown as a function of wavelength and dopant concentration. In modern MOSFETs and BJTs, the doping level of the source and emitter, respectively, generally lie between 10¹⁹ cm⁻³ to 10²¹ cm⁻³, which give rise to significant FCA that is suitable for the transistor detector absorber region. FIG. 8 shows the momentum MFP of electrons in silicon as a function of energy and dopant concentration. After an electron absorbs an infrared photon via FCA, it can move a distance on the order of the MFP before changing direction, and eventually losing energy, through scattering. An important advantage of the MOSFET-based embodiments of the present invention is that the width of the absorber-barrier junction can be made very narrow (on the order of nanometers) via the field-effect control of the channel potential by the gate voltage, improving the quantum efficiency of the device.

In one embodiment of the invention, it will be uncooled and operating at room temperature. It will be appreciated by those skilled in the art that cooling of the detector element below the ambient temperature may also be used, with a projected increase in device performance due to reduced dark current and longer mean free paths. In some embodiments of the invention, an optical lens may be placed above the device to concentrate light on the infrared window and absorber region. An interferometric filter may also be placed above the device to select a specific infrared wavelength for detection. The possibility of fabricating the present invention using the established structures and techniques of large-scale semiconductor transistor chip manufacturing is also advantageous for manufacturing focal plane arrays with improved device-to-device uniformity.

While the foregoing description of the invention focuses on infrared radiation detection using FCA, the same principle may be utilized for bias-tunable detection of short wavelength radiation, including visible and ultraviolet light, by utilizing interband absorption in the absorber region. In such cases, valence band electrons will be energetically excited into the conduction band by incident radiation with energies above the semiconductor band gap of the absorber region. If the energy of the incident photons exceeds the sum of the semiconductor band gap and the energetic potential difference between the absorber and barrier regions, these electrons may diffuse towards the collection region and induce a photocurrent in the same fashion as previously described. By tuning the barrier height via transistor biasing, the cutoff wavelength of the detectable radiation may be varied.

While the foregoing description of the invention concentrates on a few particular embodiments of the invention, using silicon planar npn BJTs and n-type MOSFETs as the basic underlying structure, those skilled in the art will perceive that variations and equivalents of the specific embodiment are possible and encompassed. It is understood that with appropriate change of substrate or dopant material, a non-silicon and/or P-type semiconductor transistor formed from other suitable substrates, whether of another channel material like gallium arsenide or a different wafer type such as silicon-on-insulator (SOI), may be used. Those skilled in the art will also appreciate that variations in the dopant concentrations, regions, layers, and geometries are possible within the basic structure depicted here. Furthermore, those skilled in the art will understand that the choice of a nonplanar transistor structure may be substituted for the generic planar configurations illustrated and discussed here. The invention should therefore not be limited by the above described embodiment, method, and examples, but by all embodiments and methods within the scope and spirit of the invention as claimed.

What is claimed is:

1) A three-terminal semiconductor transistor-like photodetector comprising: (a) an absorber region connected to a first terminal wherein photons excite carriers substantially above thermal energy of said absorber region, (b) a barrier region with a barrier potential controlled by a terminal voltage of a second terminal wherein carriers from said absorber region with thermal energy are blocked and said photo-excited carriers are allowed, and (c) a collection region connected to a third terminal to collect said photo-excited carriers, whereby said photons are detected by measuring the carrier current from said third terminal of said collection region.

2) The invention in claim 1, wherein (a) said absorber region is made of the emitter of a bipolar junction transistor (BJT), (b) said barrier region is made of the base of said BJT, and (c) said collection region is made of the collector of said BJT, whereby said barrier potential of said barrier region is controlled by said terminal voltage of said base.

3) The invention in claim 1, wherein (a) said absorber region is made of the source of a field effect transistor (FET), (b) said barrier region is made of the channel of said FET, and (c) said collection region is made of the drain of said FET, whereby said barrier potential of said channel is controlled by said terminal voltage of the gate of said FET.

4) The invention in claim 2, wherein free carrier absorption in said absorber region is utilized to detect photons with energies in excess of the barrier height of said barrier potential between said base and said emitter.

5) The invention in claim 3, wherein free carrier absorption in said absorber region is utilized to detect photons with energies in excess of the barrier height of said barrier potential between said source and said channel.

6) The invention in claim 3, wherein interband absorption in said absorber region is utilized to detect photons with energies in excess of the sum of the band gap energy of said absorber region and the barrier height of said barrier potential between said source and said channel.

7) The invention in claim 1, further including an amplification mechanism wherein said carrier current from said photo-excited carriers is amplified by carrier impact ionization at the junction between said barrier and said collection regions, so that the signal to noise ratio can be enhanced.

8) The invention in claim 3, wherein the substrate of said FET is independently biased to provide an additional degree of control over said barrier potential between said source and said channel.

9) The invention in claim 1, wherein the area directly above said absorber region is covered by one or more insulating dielectric materials such that said photons incident from above said absorber region can penetrate to said region with minimal attenuation before exciting said carriers.

10) The invention in claim 1, wherein a lens is placed above said photodetector so that said photons incident from above said photodetector are focused onto said absorber region.

11) The invention in claim 2, wherein said BJT is made of a single heterojunction bipolar structure, with a first semiconductor material comprising said emitter and a second semiconductor material comprising said base and said collector.

12) The invention in claim 2, wherein said BJT is made of a single heterojunction bipolar structure, with a first semiconductor material comprising said emitter, a second semiconductor material comprising said base, and another layer of said first semiconductor material comprising said collector.

13) The invention in claim 2, wherein said BJT is made of a double heterojunction bipolar structure, with a first semiconductor material comprising said emitter, a second semiconductor material comprising said base, and a third semiconductor material comprising said collector.

14) The invention in claim 1, wherein said photodetector is made of silicon, silicon germanium, or some heterostructure thereof.

15) The invention in claim 1, wherein said photodetector is made of an III-V semiconductor, some alloy thereof, or some heterostructure of III-V semiconductors.
